(19) United States
(12) Patent Application Publication
(10) Pub. No.: US 2012/0161185 A1
(43) Pub. Date: Jun. 28, 2012

(54) LIGHT EMITTING DIODES

(76) Inventor: Tao Wang, Sheffield (GB)

(21) Appl. No.: 13/379,260

(22) PCT Filed: Jun. 14, 2010
(86) PCT No.: PCT/GB2010/050992

§ 371 Date: Mar. 8, 2012

(30) Foreign Application Priority Data
Jun. 19, 2009 (GB) 0910619.6
Oct. 12, 2009 (GB) 0917794.0
Apr. 1, 2010 (GB) 1005582.0

(51) Int. Cl. H01L 33/50

(52) U.S. Cl. 257/98; 438/29; 257/E33.06

(57) ABSTRACT

A light emitting device comprises first and second semiconductor layers (14,16) and an emitting layer (18) between the semiconductor layers (14,16), arranged to form a light emitting diode,-a gap (30) in one of the layers; and a metal (34) located in the gap (30) and near enough to the emitting layer (18) to permit surface plasmon coupling between the metal (34) and the emitting layer (18).

### FIELD OF THE INVENTION

The present invention relates to light emitting diodes (LEDs), in particular to white LEDs, though it can also be used in LEDs of other colours.

### BACKGROUND TO THE INVENTION

The development of white solid-state lighting, mainly based on III-nitride blue LED chips with yellow phosphor, is currently becoming extremely important due to the increasing world-wide energy-shortages and threats of global warming. White light emitting diodes (LEDs) currently commercially available are generally fabricated based on blue epi-wafers, with high crystal quality, and are generally very expensive. This also causes such LEDs to have a high price and thus limits their applications in general illumination. Therefore, there is a need to develop a new technology for fabrication of LEDs, and in particular white-LEDs, with higher luminous efficacies but at a low price that can be easily accepted by the market in order to replace traditional lighting sources. However, there exist a number of challenges in order to further improve the luminous efficacy of white LEDs.

First of all, higher luminous efficacy of white LEDs requires a blue-LED with high internal quantum efficiency (IQE). The IQE of LEDs is generally accepted to be determined by the crystal quality of the LED epi-wafer. It is extremely difficult to make further improvement through optimization of the epitaxial growth.

The IQE can be significantly improved by a surface plasmon (SP) coupling effect between an LED's emitting layers, such as quantum well (QW) layers, and some certain metal (which have a plasmon energy close to or the same as the emitting energy of the emitting layers) deposited in a proximal QW, meaning that very high IQE can be achieved using a standard LED epi-wafer even without the best crystal quality. However, the enhancement in internal quantum efficiency resulting from such SP coupling has only been effectively applied in surface QW (not multiple QW) structures with a thin capping GaN layer (a few nanometer thick), whereas almost all the blue epi-wafers with high performance require multiple quantum well (MQW) emitting regions and a thick p-type GaN capping layer (˜200 nm thick).

It has been suggested to deposit metal islands in an LED's emitting layers, by halting epitaxial growth immediately before or during formation of the emitting layers, depositing the metal islands, and then resuming epitaxial growth of the emitting layers and the remainder of the LED. However, such as method requires ex-situ deposition due to unavailability of pre-cursor. Furthermore, deposition of such metal islands will lead to massive degradation in optical performance of the emitting layers, which may eventually quench the emission. In practice, this method would degrade the lattice structure of the emitting layers and may ultimately lead to malfunction of the LED.

Secondly, there exists a self-absorption issue in current fabrication of phosphor-conversion white LEDs. This means that light generated within the device can be absorbed again by the phosphor as the emission wavelength of phosphor is normally close to its absorption wavelength, reducing the overall efficiency.

Another issue is how to further improve the efficiency of the energy transfer from the blue LED to the wavelength-conversion material such as yellow phosphor. The intensity of the blue light generally remains much higher than the yellow emission from the wavelength-conversion material, leading to a severe colour rendering issue and the bluish tinge to most current white LEDs.

### SUMMARY OF THE INVENTION

The invention provides a light emitting device comprising: first and second semiconductor layers and an emitting layer between the semiconductor layers, arranged to form a light emitting diode; a gap in one of the layers; and a metal located in the gap near enough to the emitting layer to permit surface plasmon coupling between the metal and the emitting layer.

Generally only some of the metal in the gap will be near enough to the emitting layer to permit surface plasmon coupling between the metal and the emitting layer. There may also be metal in the gap that is not close enough for surface Plasmon coupling.

The device may comprise a mixture formed from the metal, which may be in the form of metal particles, and a support material. The mixture may be located in the gap and near enough to the emitting layer to permit surface plasmon coupling between the metal particles and the emitting layer.

Optionally, the support material comprises a wavelength conversion material or insulating transparent material or semi-insulating transparent material.

Optionally, the metal or the mixture is located directly adjacent or in contact with a surface of the gap.

Optionally, the gap extends part but not all of the way through the thickness of the second semiconductor layer towards the emitting layer, but the gap may extend through the second semiconductor layer with part of the gap bounded by a surface of the emitting layer.

Optionally, the metal or the mixture is located in the gap directly adjacent, or in contact with, said surface of the emitting layer.

Optionally, a metal containing layer, which may comprise a layer of metal or a layer of the mixture, is provided directly adjacent, or in contact with, said surface of the emitting layer. The layer may be continuous, or discontinuous.

Optionally, the gap extends through the thickness of the emitting layer and part of the gap is bounded by a surface of the first semiconductor layer.

Optionally, the first semiconductor layer is formed on a substrate.

The device may further comprise a contact layer adjacent and in electrical contact with the second semiconductor layer so as to close off at least part of the gap.

Optionally, pillars are formed from at least one of the layers by means of the gap being formed between the pillars. The average shortest distance between two adjacent pillars, measured between the respective sides of two adjacent pillars, may be less than 500 nm and preferably less than 200 nm.

The device may comprise a plurality of said gaps that are separate from each other so that the metal or the mixture is in the form of pillars. The average diameter of the pillars may be less than 500 nm and preferably less than 200 nm.

The invention also provides a method of producing a light emitting device comprising: forming first and second semiconductor layers and an emitting layer between the semiconductor layers; forming a gap in one of the layers; and placing a metal in the gap and near enough to the emitting layer to permit surface plasmon coupling between the metal and the emitting layer.

The method may comprise: forming a mixture from the metal, which is in the form of metal particles, and a support material; and placing the mixture in the gap and near enough to the emitting layer to permit surface plasmon coupling between the metal particles and the emitting layer.

Optionally, the support material comprises a wavelength conversion material or insulating transparent material or semi-insulating transparent material.

Optionally, the metal or the mixture is placed directly adjacent or in contact with a surface of the gap.

Optionally, the gap is formed part but not all of the way through the second semiconductor layer towards the emitting layer. The gap may be formed through the second semiconductor layer with part of the gap bounded by a surface of the emitting layer.

Optionally, the metal or the mixture is placed in the gap and directly adjacent or in contact with said surface of the emitting layer.

Optionally, a metal containing layer is provided directly adjacent or in contact with said surface of the emitting layer.

Optionally, the gap is formed through the thickness of the emitting layer and part of the gap is bounded by a surface of the first semiconductor layer.

Optionally, the first semiconductor layer is formed on a substrate.

The method may comprise forming a contact layer adjacent and in electrical contact with the second semiconductor layer so as to close off at least part of the gap.

Optionally, pillars are formed from at least one of the layers by means of the gap being formed between the pillars. The average shortest distance between two adjacent pillars, measured between the respective sides of two adjacent pillars, may be less than 500 nm and preferably less than 200 nm.

The method may comprise forming a plurality of said gaps that are separate from each other so that the metal or the mixture is in the form of pillars. The average diameter of the pillars may be less than 500 nm and preferably less than 200 nm.

The device may be a fabricated device, that is, it is produced by device fabrication after e.g. epitaxial growth.

White LED devices according to some embodiments of the invention can respond to the challenges described above using a hybrid nanotechnology, for example an III-nitride/polymer or phosphor hybrid. In some embodiments an array of nano-pillars, on a scale of 100s of nm, are fabricated into a multiple quantum well (MQW) based III-nitride blue LED and surrounded by a wavelength-conversion polymer or phosphor mixed with metal nano-particles.

It is thought that, to permit SP coupling between a metal and the emitting layers, the distance between the two needs to be 100 nm or less. To maximise the effect of SP coupling, it is thought that the distance between them should be about 50 nm or less, or more specifically, 47 nm or less, which will be referred to herein as a ‘near field’ distance. Most preferably the distance between the metal and the emitting layers is effectively zero.

Preferred embodiments of the present invention will now be described by way of example only with reference to the accompanying drawings.

### BRIEF DESCRIPTION OF THE DRAWINGS

FIG. 1 is a section through a light emitting device according to an embodiment of the invention;

FIG. 2 shows examples of nano-pillar arrays fabricated using Ni film with different thickness;

FIG. 3 is a graph showing luminescence intensity for a number of devices according to the invention;

FIG. 4 is as horizontal section through the device of FIG. 1;

FIG. 5 is a horizontal section through a device according to a further embodiment of the invention;

FIG. 6 is a section through a light emitting device according to a further embodiment of the invention;

FIG. 7 is a section through a light emitting device according to a yet further embodiment of the invention; and

FIG. 8 is a section through a light emitting device according to another embodiment of the invention.

### DESCRIPTION OF THE PREFERRED EMBODIMENTS

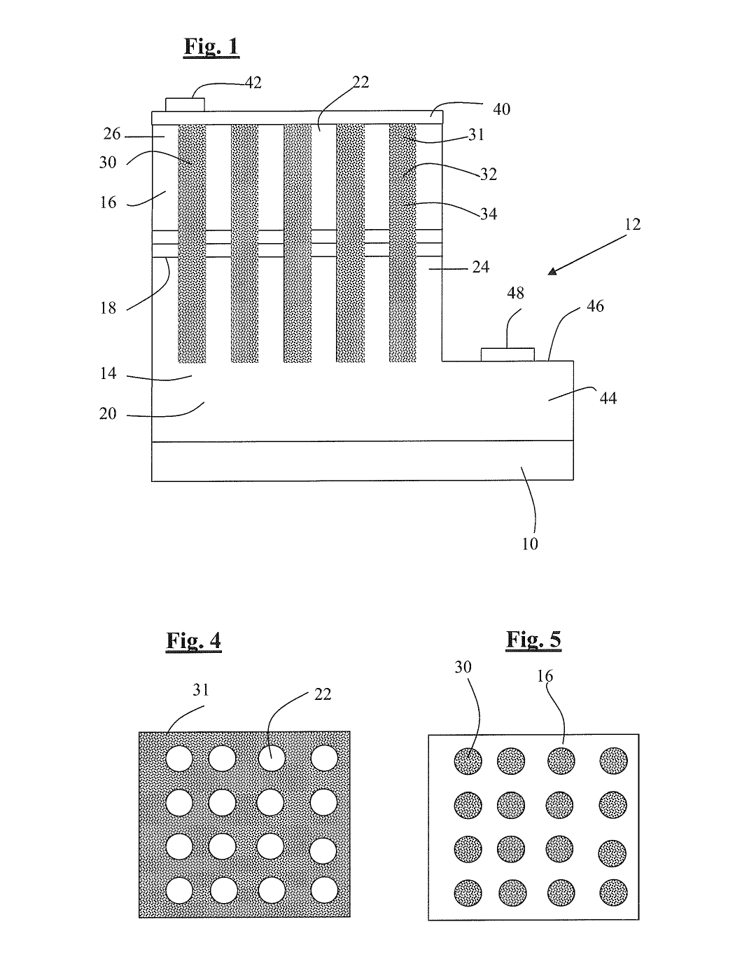

Referring to FIG. 1, a light emitting device according to an embodiment of the invention comprises a substrate 10, which in this case comprises a layer of sapphire, with a semi-conductor diode system 12 formed on it. The diode system 12 comprises a lower layer 14 and an upper layer 16, with emitting layers 18 between them. The lower layer 14 is an n-type layer formed of n-doped gallium nitride (n-GaN), and the upper layer 16 is a p-type layer formed of p-doped gallium nitride (p-GaN). The emitting layers in this embodiment are formed of InₓGa₁₋ₓN which forms InₓGa₁₋ₓN quantum well (QW) layers and In_{y}Ga_{1-y}N which forms barrier layers (where x>y, and x or y from 0 to 1). These therefore provide multiple quantum wells within the emitting layers 18. In another embodiment, there is a single In_{z}Ga_{1-z}N layer (z from 0 to 1) which forms a single emitting layer.

When an electric current passes through the semiconductor diode system 12, injected electrons and holes recombine in the emitting layers 18 (sometimes referred to as active layers), releasing energy in the form of photons and thereby emitting light. The p-type layer 16 and n-type layer 14 each have a larger band gap than the emitting layers.

Structurally the semi-conductor diode system 12 comprises a continuous base layer 20 with a plurality of nano-pillars 22 projecting from it. The n-type layer 14 makes up the base layer and the lower part 24 of the nano-pillars, the p-type layer 16 makes up the upper part 26 of the nano-pillars, and the emitting layers 18 make up an intermediate part of the nano-pillars 22. Therefore the p-type layer 16, the emitting layers 18, and part of the n-type layer are all discontinuous, and the base layer 20 closes the bottom end of the gaps 30. The nano-pillars 22 are of the order of hundreds of nanometers in diameter, i.e. between 100 and 1000 nm.

The gaps 30 in the discontinuous layers, between the nano-pillars 22, are filled with a mixture 31 of wavelength-conversion material 32 (which could be an insulating transparent material or semi-insulating transparent material) 32 and metal particles 34. Thus the wavelength-conversion material acts as a support material to support the metal particles 34 in the gaps 30. This mixture 31 fills the gaps 30 and forms a layer from the base layer 20 up to the top of the nano-pillars 22. In this embodiment it will be appreciated that the gaps 30 are in fact joined together to form one interconnected space that surrounds all of the nano-pillars 22. If the nano-pillars 22 are formed so that the maximum distance between adjacent nano-pillars 22 is, say, 200 nm then the maximum distance from any one of the metal particles 34 to a surface of one of the nano-pillars 22 is 100 nm. In which case, any of the metal particles 14 that is coplanar with the emitting layers 18 is in a position which permits surface plasmon coupling. Moreover, the metal particles 14 are suspended in the wavelength conversion material 32 and distributed randomly throughout it. Therefore, in this case, most of the particles 14 will be positioned less than 100 nm (and for some particles, effectively zero nm) from a surface of one of the nano-pillars 22.

The wavelength-conversion material 32 in this case is a polymer material, but could be a phosphor; in addition, cadmium sulphide may be used but many suitable types of wavelength-conversion material 32 will be apparent to those skilled in the art.

The metal particles 34 are silver. The size of the metal particles 34 is from a few nm to about 1 μm, depending in part on the size of the pillars, and the particle concentration in the wavelength-conversion material 32 is from 0.0001% w/w up to 10% w/w. In other embodiments the metal particles 34 can be gold, nickel or aluminium, for example. The choice of metal is based on the wavelength, or frequency of light from the emitting layers 18; for example silver is preferred for blue LEDs but aluminium is preferred for ultraviolet LEDs.

Because the gaps 30 extend through the emitting layers 18, parts of the sides of the gaps 30 are formed by the emitting layer material, so the emitting layer material is exposed to the gaps 30. The mixture 31 is positioned directly adjacent or in contact with the sides of the gaps 30 i.e. there are no insulating layers or other materials positioned in the gaps 30 between the mixture 31 and the sides. Therefore some of the metal particles 34 suspended in the mixture 31 are a near field distance (47 nm or less) from an exposed surface of the emitting layers, which permits improved surface plasmon coupling. Some of the metal particles 34 are suspended in the mixture 31 such that they are very near, or even in contact with, an exposed surface of the emitting layers 18. Also the polymer wavelength-conversion material 32 is close to, and in contact with, the exposed parts of the emitting layers 18. That is, the distance from an exposed surface of the emitting layers 18 to at least some of the metal particles 34, and to the wavelength conversion material 32, is effectively zero.

A transparent p-contact layer 40 extends over the tops of the nano-pillars 22, being in electrical contact with them, and also extends over the top of the gaps 30 closing their top ends. A p-contact pad 42 is formed on the p-contact layer 40. A portion 44 of the base region 14 extends beyond the nano-pillars 22 and has a flat upper surface 46 on which an n-contact 48 is formed.

The device of FIG. 1 is produced by first forming the nano-pillar structure. This is done by forming the n-type layer 14 on the sapphire substrate 10, forming the emitting layers 18, such as the quantum well layers, on the n-type layer 14, forming the p-type layer 16 over the emitting layers 18, and then etching down through the layers 14, 16, 18 to form the gaps 30, leaving the nano-pillars 22. To control the etching, a mask is formed on the p-type layer 16, in a known manner, by first forming a layer of SiO₂ thin film over the p-type layer 16, followed by forming a nickel layer with thickness ranging from 5 to 50 nm. The sample is subsequently annealed under flowing N₂ at temperature 600-900° C. for 1 to 10 min. Under such conditions, the thin nickel layer can be developed into self-assembled nickel islands with a scale of 100s of nm on the SiO₂ surface. The self-assembled nickel islands then serve as a mask to etch the underlying oxide into SiO₂ nanorods on the p-GaN surface by reactive ion etching (RIE). Finally, the SiO₂ nanorods serves as a second mask, and then using inductively coupled plasma (ICP) etching the p-GaN layer is dry-etched down through the p-type layer 16, the emitting layers 18, and part way through the n-type layer 14, until the structure of FIG. 1 is achieved. The etching is monitored, for example using a 650 nm laser, until the desired depth is reached. This leaves the nano-pillar structure. The Ni islands and SiO₂ can be easily wet-etched away using mixed acids (such as HNO₃:CH₃OOH:H₂SO₄ and HF solution).

A standard photolithography can be carried out in order to have the region 44 of the base layer with a flat upper surface 46 on which the n-type contact can be formed.

Once the nano-pillar structure has been formed, the mixture 31 of a wavelength-conversion material 32, and metal particles 34 is inserted into the gaps 30 by spin coating. This mixture 31 is added into the gaps 30 until they are full up to the level of the tops of the nano-pillars 22, and then any surplus is removed so that the top of the mixture 31 and the top of the non-pillars 22 form a substantially flat surface.

The transparent p-contact layer 40 is then formed over the top of the pillars 22, closing the top end of the gaps 30 and making electrical contact with the tops of the nano-pillars 22. Finally the p-contact pad 42 is formed on the p-contact layer 40, and the n-contact 48 is formed on the flat surface 46.

In operation, when an electrical potential is applied across the p- and n-contacts 42 and 48, light of one wavelength or wavelength spectrum, in this case predominantly blue, is emitted from the emitting layers 18. Some of this light is absorbed by the wavelength-conversion material 32, and re-emitted as light of a different wavelength or wavelength spectrum, in this case yellow light. The blue and yellow light together produce light of a sufficiently broad spectrum for it to be white.

The advantage of using the surface plasmon coupling effect to enhance IQE can be fully exploited in this modification to a standard blue MQW epi-wafer with a capping layer of any thickness. This is because some of the metal particles 34 are a near field distance (47 nm or less) from the emitting quantum well material in the emitting layers 18 (at the side-wall of the nano-pillars 22) and so permit effective surface plasmon coupling, and the distance between some of those metal particles 34 and the emitting layers 18 will be effectively zero. The surface plasmon coupling effect can be significantly enhanced when the distance between the emitting layers 18 and the metal particles 34 can be down to effectively zero.

The mechanism of LED luminescence wavelength-conversion using polymers is based on non-radiative Foster energy transfer. As such energy transfer relies on Coulomb interactions the distance between the emitting layers 18 and the wavelength-conversion material 32 is critical.

The energy transfer rate F can be simply described as: Γ˜R⁻⁴, where R is distance between emitting QW and polymer. In the LED device described, the distance R can approach zero, and the transfer rate can be greatly increased. This can lead to a significantly improved efficiency of wavelength-conversion for yellow emission (550-584 nm), and thus provide improved colour rendering.

A conjugated polymer can be chosen having a luminescence emission at wavelengths far below its absorption edge, which can be up to 200 nm. By selecting and optimising the polymer material losses due to self-absorption can be minimized.

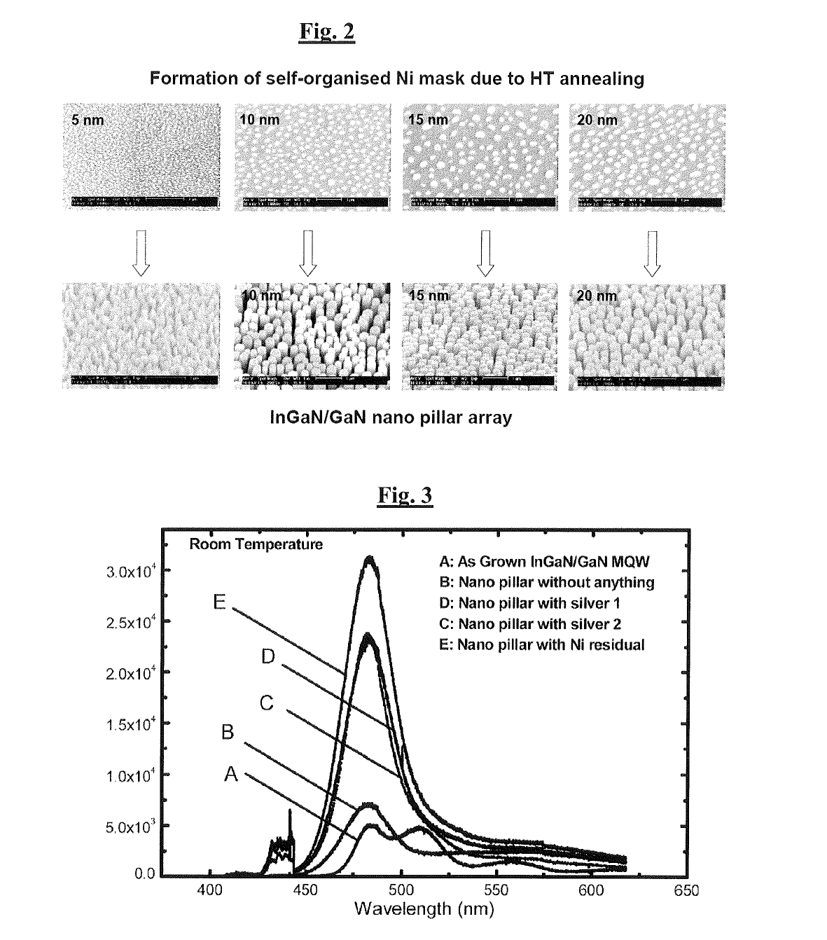

Referring to FIG. 2, the final size of the nano-pillars 22 in the method described above depends on, among other things, the thickness of the nickel layer used in the production of the device. The top four images are of the self-organized nickel mask resulting from the annealing step, for nickel layers of 5 nm, 10 nm, 15 nm and 20 nm thickness respectively. The bottom four images are of the resulting nano-pillar structures.

Referring to FIG. 3, the luminescent intensity of various devices formed as described above was tested. The intensities were for devices formed as follows:
A: the device as grown with multiple emitting layers, but before the formation of the nano-pillar structure 22.
B: the device after formation of the nano-pillar structure 22, but with no polymer/metal mixture 31.
C: the device with nano-pillar structure 22 with a polymer/silver particle mixture 31.
D: the device with nano-pillar structure 22 with a polymer/silver particle mixture 31. The silver concentration is slightly different from that in sample C.
E: the device with nano-pillar structure 22 with a polymer/nickel particle mixture 31.

As can be seen from this figure, the intensity varies significantly between these examples, but notably all of the examples with a polymer/metal mixture 31 have significantly higher intensity than either the simple as-grown device or the device with nano-pillars 22 but no polymer/metal mixture 31.

The improved intensity results from the surface plasmon coupling effect as a result of some of the metal particles 34 (for instance, Ni or silver) being a near field distance from the emitting layers 18 (for instance, InₓGa₁₋ₓN: well/In_{y}Ga_{1-y}N:barrier multiple quantum wells (x>y, and x or y from 0 to 1)), where the metal particles 34 are supported in the polymer material filling the gaps 30 among the nano-pillars 22 containing InₓGa₁₋ₓN/In_{y}Ga_{1-y}N multiple quantum wells in the emitting layers 18.

FIG. 4 shows the device of FIG. 1 in plan view. It will be appreciated that the semiconductor layers can be structured in different ways whilst still achieving the same effect. For example, referring to FIG. 5, in a further embodiment, the gaps 30 are in the form of a series of separate bores of circular cross section extending down into the semiconductor layers. The layers of semi-conductor material 16 around the bores 30 are therefore all continuous with apertures through them, rather than being discontinuous as in the embodiment of FIG. 1. The diameters of the bores are of the order of hundreds of nanometers in diameter, i.e. between 100 and 1000 nm.

It will be appreciated that other structures can be used, for example the gaps can be in the form of a series of parallel slots, so that the semiconductor material, instead of being in the form of vertical pillars as in FIG. 1, is in the form a series of vertical sheets.

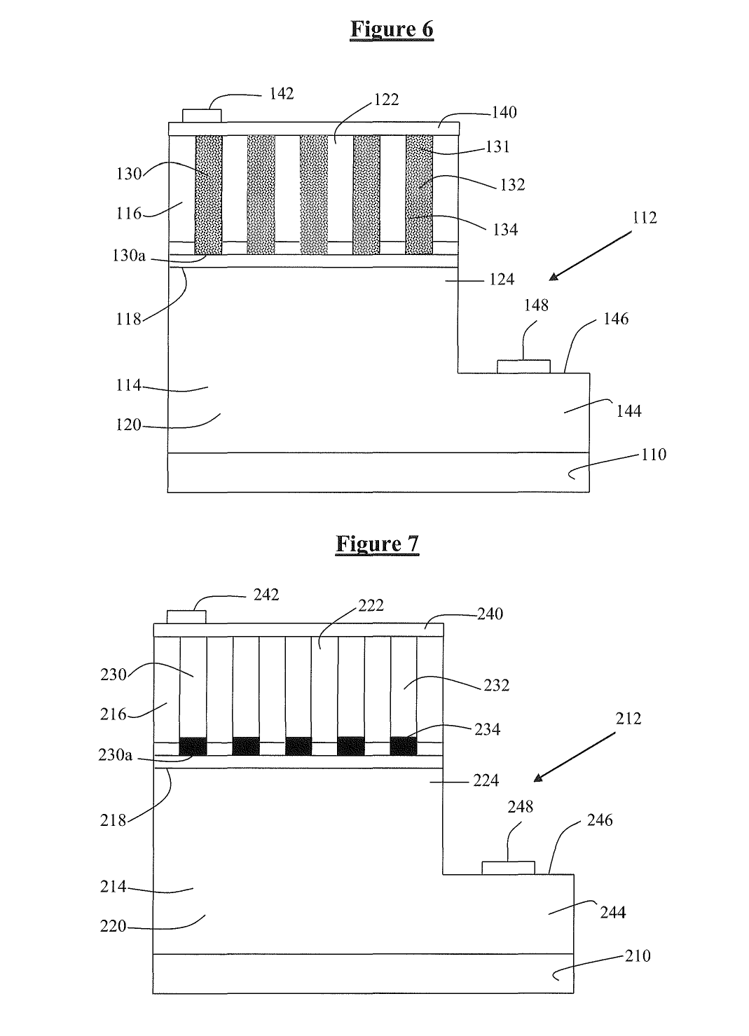

Those skilled in the art will appreciate alternative embodiments which bring about the advantageous surface plasmon coupling effect as a result of some of the metal particles 34 being a near field distance from the emitting layers 18 (and for some of those metal particles 34 the distance is effectively zero), thereby also achieving improved intensity results. Three such different arrangements are shown in FIGS. 6, 7 and 8.

Referring first to FIG. 6, a light emitting device according to a further embodiment is arranged in a similar manner to the embodiment of FIG. 1 described above, with corresponding parts indicated by reference numerals increased by 100. In this embodiment the gaps 130 extend from the bottom of the p-contact layer 140 only part way through the emitting layers 118 so that the bottom ends of the gaps 130 are within the emitting layers 118. This has an advantage in that the bottom ends 130a of the gaps 130 constitute extra exposed surface area of the emitting layers 118 within the gaps 130. Thus the amount of surface area of the emitting layers 118 with which the metal particles 134 and the wavelength conversion material 132 can interact via surface plasmon coupling can be increased by way of this arrangement. The mixture 131 of the metal particles 134 and the wavelength conversion material 132 is directly adjacent or in contact with the emitting layers 118 i.e. there is no other material positioned between the mixture 131 and the sides and bottom ends 130a of the gaps 130. Accordingly, in this embodiment the distance from an exposed surface of the emitting layers 118 to at least some of the metal particles 134, and to the wavelength conversion material 132, is effectively zero.

In a modification to this embodiment (not shown), the gaps extend downwards from the bottom of the p-contact layer through the upper layer only as far as the top surface of the emitting layers, so that the top surface of the emitting layers forms the bottom ends of the gaps. That is, the gaps are bounded at their bottom ends by the top surface of the emitting layer, and at their sides by the upper layer. The metal and the wavelength conversion material are both in direct contact with the emitting layers at the same time.

Referring now to FIG. 7, a light emitting device of a further embodiment is arranged in a similar manner to the embodiment of FIG. 6, with corresponding parts indicated by reference numerals increased by 100. In this embodiment, a metal deposit 234 is provided directly on the surface of the emitting layers 218 exposed within the gaps 230 forming a metal layer. The metal deposit 234 may be provided by means of a thermal or electron-beam evaporator, or any other suitable evaporator method known to those skilled in the art. The metal deposit 234 is generally thicker on the surface of the emitting layers 218 exposed at the bottom ends 230a of the gaps 230 than it is on the sides of the gaps 230. In practice, there is a threshold for the thickness of a deposited layer; to deposit a continuous layer that is thinner than the threshold is at best infeasible and in many cases impossible. Therefore, when the thickness of the metal deposit layer 234 is below the threshold (for state of the art technology, say, 50 nm or less on the bottom ends 230a of the gaps 230), the metal deposit 234 is discontinuous or in some cases not present on the sides of the gaps 230. Each of the gaps 230 further contains a wavelength-conversion material 232, in direct contact with parts of the surface of the emitting layers 218 between the discontinuous metal deposits, to absorb and re-emit at a changed frequency light from the emitting layers 218. Thus in this embodiment, similarly to the embodiments already described, the metal deposit 234 forms a number of discrete volumes of metal which are not in contact with each other and so does not extend continuously from the surface of the emitting layers 218 along the surface of the p-type layer 216 exposed in the side walls of the gaps 230. This ensures that there is no continuous body of metal extending substantially across different semiconductor layers, thereby avoiding any possibility of providing an electrical short circuit by means of the metal deposit 234. It also means that both the metal and the wavelength conversion material 232 are in contact with the emitting layer 218, as the wavelength-conversion material 232 contacts the emitting layers 218 between the discrete volumes of the metal deposit 234. Corresponding modifications could also be made to the embodiments of FIG. 1 and FIG. 6.

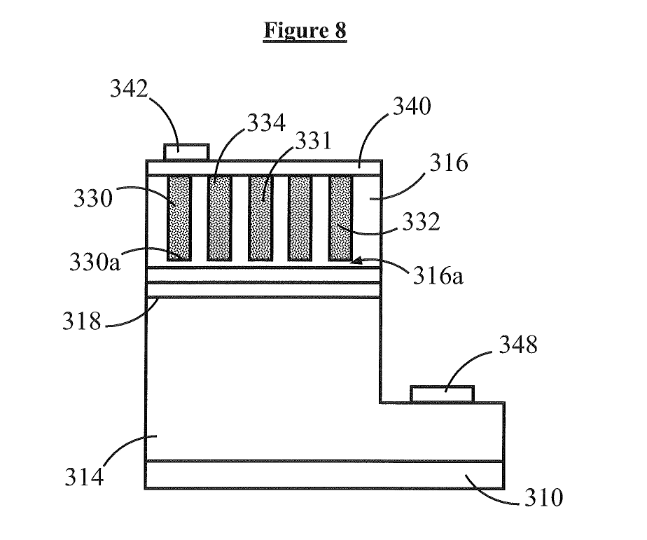

Referring now to FIG. 8, a light emitting device of yet another embodiment is arranged in a similar manner to the embodiment of FIG. 7, with corresponding parts indicated by reference numerals increased by 100. As shown in FIG. 8, the gaps 330 are formed from the top of the p-type layer 316 (i.e. the bottom of the p-contact layer 340) almost to the emitting layers 318. A mixture 331 of a support material 332 (in this embodiment a phosphor wavelength conversion material 332) and metal particles 334 fills the gaps 330 to the top i.e. to the bottom of the p-contact layer 340. The bottoms 330a of the gaps 330 are positioned near enough to the top of the emitting layers 318 to permit surface plasmon coupling between the emitting layers 318 and the metal particles 334 in the gap 330 (which are suspended in). A thin portion 316a of the p-type layer 316 separates the top of the emitting layers 318 from the bottom of the gap 330, thereby providing electrical insulation between the emitting layers 318 and the metal particles 334. The thickness of the thin portion 316a, measured perpendicularly to the plane of the boundary between the top of the emitting layers 318 and the bottom of the p-type layer 316, is small enough to permit said surface plasmon coupling i.e. 100 nm or less, and preferably 47 nm or less. For example, the thin portion 316a could be less than 30 nm thick and preferably less than 20 nm thick.

In a further modification to any of the described embodiments, the metal particles 34, 134, 334, or the metal deposit 234, and the wavelength conversion material 32, 132, 232, 332 are both replaced by a body of metal which substantially fills each of the gaps 20, 130, 230 (i.e. the gaps do not contain any support material/wavelength conversion material), the body of metal thereby directly contacting the entire exposed surface of the emitting layer 18, 118, 218 and the upper layer 16, 116, 216. It is known in the art that forming ohmic contact between a metal and a semiconductor layer is a non-trivial task, in particular, for p-type or undoped III-nitrides such as GaN. Only certain types of metal can form ohmic contact with semiconductor materials, and the type of metal used to form an ohmic contact with a semiconductor material must be specifically chosen on the basis of the work function of the metal and the doping level of the type of semiconductor material. Therefore, this modification can be achieved by choosing the body of metal to be of a type such that no ohmic contact can be formed between the body of metal and any of the semiconductor layers. For example, silver or aluminium can be used for SP-enhanced IQE as described above, but cannot be used as an ohmic contact for p-type or undoped GaN.

In all the alternative embodiments described above, the metal used, as well as the wavelength conversion material, can be chosen from any of the suitable alternatives described above for the embodiment of FIG. 1. The light emitting device of the present invention has been described with reference to white LED embodiments, but in modifications to the described embodiments coloured LEDs are provided, which do not require light from the emitting layer to be absorbed, converted to light of a different wavelength and mixed together. In one particular modification to the embodiment of FIG. 1, or FIG. 6, the LED is an ultra violet LED having an AlGaN light emitting layer, with aluminium particles supported in a transparent polymer or the like.

In another embodiment the LED is a green LED emitting at a wavelength of between 500 and 560 nm. The nano-particles can be of silver, platinum, nickel or gold and, as will be appreciated, the size of the particles can be chosen so as to determine the wavelength of the emitted light.

1-34. (canceled)

35. A light emitting device comprising:
first and second semiconductor layers and an emitting layer between the semiconductor layers, the layers being arranged to form a light emitting diode;
wherein one of the layers has a gap therein; and
a metal located in the gap and near enough to the emitting layer to permit surface plasmon coupling between the metal and the emitting layer.

36. A device according to claim 35 comprising a mixture formed from the metal, which is in the form of metal particles, and a support material, the mixture being located in the gap.

37. A device according to claim 36 wherein the support material comprises a wavelength conversion material.

38. A device according to claim 35 wherein the gap has a surface and the metal is located directly adjacent said surface.

39. A device according to claim 36 wherein the gap has a surface and the mixture is located directly adjacent said surface.

40. A device according to claim 35, wherein the gap extends part but not all of the way through the second semiconductor layer towards the emitting layer.

41. A device according to claim 35 wherein the gap extends through the second semiconductor layer, the emitting layer has a surface, and part of the gap is bounded by said surface of the emitting layer.

42. A device according to claim 41, wherein the metal is located in the gap directly adjacent said surface of the emitting layer.

43. A device according to claim 36 wherein the gap extends through the second semiconductor layer, the emitting layer has a surface, part of the gap is bounded by said surface of the emitting layer, and the mixture is located in the gap directly adjacent said surface of the emitting layer.

44. A device according to claim 41 comprising a layer which is provided in contact with said surface of the emitting layer, and which contains the metal.

45. A device according to claim 42, wherein the gap extends through the emitting layer and part of the gap is bounded by a surface of the first semiconductor layer.

46. A device according to claim 35 further comprising a substrate, wherein the first semiconductor layer is formed on the substrate.

47. A device according to claim 35 further comprising a contact layer adjacent, and in electrical contact with, the second semiconductor layer so as to close off at least part of the gap.

48. A device according to claim 35 wherein at least one of the layers forms pillars by means of the gap being formed between the pillars.

49. A device according to claim 48 wherein the average shortest distance between two adjacent pillars, measured between the respective sides of two adjacent pillars, is less than 500 nm and preferably less than 200 nm.

50. A device according to claim 36, comprising a plurality of said gaps that are separate from each other so that the mixture is in the form of pillars,

51. A device according to claim 50, wherein the average diameter of the pillars is less than 500 nm and preferably less than 200 nm.

52. A method of producing a light emitting device comprising:
forming first and second semiconductor layers and an emitting layer between the semiconductor layers;
forming a gap in one of the layers; and
placing a metal in the gap and near enough to the emitting layer to permit surface plasmon coupling between the metal and the emitting layer.

53. A method according to claim 52 wherein the placing the metal in the gap comprises:
forming a mixture from the metal, which is in the form of metal particles, and a support material; and
placing the mixture in the gap and near enough to the emitting layer to permit surface plasmon coupling between the metal particles and the emitting layer.

54. A method according to claim 53 wherein the support material comprises a wavelength conversion material.

55. A method according to claim 52 wherein the metal is placed directly adjacent a surface of the gap.

56. A method according to claim 52, wherein the gap is formed part but not all of the way through the second semiconductor layer towards the emitting layer.

57. A method according to claim 52, wherein the gap is formed through the second semiconductor layer, the emitting layer has a surface, and part of the gap is bounded by the surface of the emitting layer.

58. A method according to claim 57, wherein the metal is placed in the gap and directly adjacent said surface of the emitting layer.

59. A method according to claim 58 wherein a layer containing the metal is provided in contact with said surface of the emitting layer.

60. A method according to claim 58, wherein the gap is formed through the emitting layer, the first semiconducting layer has a surface, and part of the gap is bounded by the surface of the first semiconductor layer.

61. A method according to claim 52 further comprising providing a substrate, and wherein the first semiconductor layer is formed on the substrate.

62. A method according to claim 52 further comprising forming a contact layer adjacent, and in electrical contact with, the second semiconductor layer so as to close off at least part of the gap.

63. A method according to claim 52 further comprising forming pillars from at least one of the layers by forming the gap.

64. A method according to claim 63 wherein the pillars are formed such that the average shortest distance between two adjacent pillars, measured between the respective sides of two adjacent pillars, is less than 500 nm and preferably less than 200 nm.

65. A method according to claim 53, comprising forming a plurality of said gaps that are separate from each other so that the mixture is in the form of pillars.

66. A method according to claim 65, wherein the average diameter of the pillars is less than 500 nm and preferably less than 200 nm.
